(19) United States
(12) Patent Application Publication
(10) Pub. No.: US 2026/0211053 A1
(43) Pub. Date: Jul. 23, 2026

(54) METHOD AND APPARATUS WITH BATTERY LIFE DETERMINATION

(71) Applicant: Samsung Electronics Co., Ltd., Suwon-si (KR)

(72) Inventors: Daeryong JUNG, Suwon-si (KR); Jinho Kim, Suwon-si (KR)

(73) Assignee: Samsung Electronics Co., Ltd., Suwon-si (KR)

(21) Appl. No.: 19/360,635

(22) Filed: Oct. 16, 2025

(30) Foreign Application Priority Data
Jan. 22, 2025 (KR) 10-2025-0009579

(51) Int. Cl. G01R 31/392; G01R 31/367

(52) U.S. Cl. CPC G01R 31/392; G01R 31/367

(57) ABSTRACT

A processor-implemented method includes generating remaining useful life (RUL) estimation result sets for a plurality of areas divided based on a state of the battery, using a plurality of RUL estimation models that determine an RUL of the battery, based on at least a portion of the plurality of values of the degradation parameter, determining a first weight set for a first area among the plurality of areas, based on experimental data on degradation of the battery and a first RUL estimation result set among the RUL estimation result sets, and generating a look-up table (LUT) to determine the RUL of the battery based on the first weight set.

### CROSS-REFERENCE TO RELATED APPLICATIONS

This application claims the benefit under 35 USC § 119(a) of Korean Patent Application No. 10-2025-0009579, filed on Jan. 22, 2025, in the Korean Intellectual Property Office, the entire disclosure of which is incorporated herein by reference for all purposes.

### BACKGROUND

### 1. Field

The following description relates to a method and apparatus with battery life determination.

### 2. Description of Related Art

Repeated charging and discharging cycles of lithium-ion batteries may cause degradation, resulting in a reduction of the capacity of a battery. The state of health (SOH) is typically used as a metric to quantify the degree of battery degradation, and is generally defined as the ratio of battery's current capacity to battery's original capacity when it is new. Accurately estimating the SOH of a battery may be important for various operational and safety-related reasons.

First, safe and efficient operation of a battery relies heavily on accurate estimation of a state of charge (SOC) of the battery. When the battery is degraded, the degree of battery degradation has to be reflected in an SOC estimation model to maintain the accuracy of the SOC estimation. Accordingly, precise SOH estimation directly enhances the reliability of SOC calculations for batteries that have experienced degradation.

Second, the SOH is a critical indicator for assessing the long-term usability of a battery. Typically, when the SOH of a battery falls below a certain value, the battery is considered unusable. A state in which a battery is unusable may be referred to as end of life (EOL), and depending on the purpose for which the battery is used, the EOL of the battery may be set at different SOH levels, such as 80%, 70%, or 60%. To determine whether the battery has reached EOL, the current SOH of the battery may have to be determined.

In addition to SOH estimation, a technique for estimating a remaining useful life (RUL) of a battery is gaining increasing attention. RUL estimation aims to predict the amount of time or usage cycles remaining before the battery reaches its EOL, thus enabling proactive maintenance and replacement planning.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method includes generating remaining useful life (RUL) estimation result sets for a plurality of areas divided based on a state of a battery, using a plurality of RUL estimation models that determine an RUL of the battery, based on at least a portion of a plurality of values of a degradation parameter of the battery; determining a first weight set for a first area among the plurality of areas, based on experimental data on degradation of the battery and a first RUL estimation result set among the RUL estimation result sets; and generating a look-up table (LUT) to determine the RUL of the battery based on the first weight set.

The plurality of values of the degradation parameter may be obtained based on a preset condition, and the preset condition comprises whether a number of accumulated charging/discharging cycles may reach a preset number.

The degradation parameter of the battery may comprise a state of health (SOH) of the battery.

A minimum number of values used in one or more of the plurality of RUL estimation models among the plurality of values of the degradation parameter may be a; a maximum number of values used in one or more of the plurality of RUL estimation models among the plurality of values of the degradation parameter may be b; a number of base RUL estimation models may be c; and a number of the plurality of RUL estimation models may be less than or equal to (b−a+1)×c.

The generating of the RUL estimation result sets may comprise: generating the first RUL estimation result set corresponding to the first area, using first RUL estimation models among the plurality of RUL estimation models, based on first values among the plurality of values corresponding to the first area; and generating a second RUL estimation result set corresponding to a second area among the plurality of areas, using second RUL estimation models among the plurality of RUL estimation models, based on second values among the plurality of values corresponding to the second area.

The determining of the first weight set may comprise: generating a first RUL result for the first area based on the experimental data; and determining the first weight set for the first area based on the first RUL estimation result set and the first RUL result.

The determining of the first weight set may further comprise: determining, based on the first RUL result, first candidate estimation results among estimation results of the first RUL estimation result set; and determining the first weight set for the first area based on the first candidate estimation results and the first RUL result.

In one general aspect, provided is a non-transitory computer-readable storage medium storing one or more programs including instructions that, when executed by one or more processors of an electronic device individually or collectively, cause the electronic device to perform the method described herein.

In one general aspect, an electronic device includes: one or more processors including processing circuitry; and memory including one or more storage media storing instructions that, when executed by the one or more processors individually or collectively, cause the electronic device to: generate remaining useful life (RUL) estimation result sets for a plurality of areas divided based on a state of a battery, using a plurality of RUL estimation models that determine an RUL of the battery, based on at least a portion of a plurality of values of a degradation parameter of the battery; determine a first weight set for a first area among the plurality of areas, based on experimental data on degradation of the battery and a first RUL estimation result set among the RUL estimation result sets; and generate a look-up table (LUT) to determine the RUL of the battery based on the first weight set.

The instructions, when executed by the one or more processors individually or collectively, may cause the electronic device to: generate the first RUL estimation result set corresponding to the first area, using first RUL estimation models among the plurality of RUL estimation models, based on first values among the plurality of values corresponding to the first area; and generate a second RUL estimation result set corresponding to a second area among the plurality of areas, using second RUL estimation models among the plurality of RUL estimation models, based on second values among the plurality of values corresponding to the second area.

The instructions, when executed by the one or more processors individually or collectively, may cause the electronic device to: generate a first RUL result for the first area based on the experimental data; and determine the first weight set for the first area based on the first RUL estimation result set and the first RUL result.

The instructions, when executed by the one or more processors individually or collectively, may cause the electronic device to: determine, based on the first RUL result, first candidate estimation results among estimation results of the first RUL estimation result set; and determine the first weight set for the first area based on the first candidate estimation results and the first RUL result.

In one general aspect, a mobile terminal includes a display; a battery supplying power to the display; one or more processors each including processing circuitry; and memory including one or more storage media storing instructions that, when executed by the one or more processors individually or collectively, cause the mobile terminal to: determine a look-up table (LUT) value corresponding to a target timepoint at which a request to determine a remaining useful life (RUL) of the battery based on a predefined LUT for the battery is obtained, wherein the LUT value comprises a weight set for a plurality of RUL estimation models; generate an RUL estimation result set based on at least a portion of a plurality of values of a degradation parameter of the battery using one or more of the plurality of RUL estimation models; and determine the RUL of the battery based on the weight set of the LUT value and the RUL estimation result set.

The instructions, when executed by the one or more processors individually or collectively, may cause the mobile terminal to: determine the one or more RUL estimation models based on the weight set.

The instructions, when executed by the one or more processors individually or collectively, may cause the mobile terminal to: determine first values among the plurality of values corresponding to a first RUL estimation model among the one or more RUL estimation models; and generate a first RUL estimation result of the RUL estimation result set based on the first values and the first RUL estimation model.

Other features and aspects will be apparent from the following detailed description, the drawings, and the claims.

### BRIEF DESCRIPTION OF THE DRAWINGS

FIG. 1 illustrates an example configuration of an electronic device according to one or more embodiments.

FIG. 2 illustrates an example method of generating an LUT used to determine an RUL of a battery according to one or more embodiments.

FIG. 3 illustrates an example method of generating an RUL estimation result set for a plurality of areas according to one or more embodiments.

FIG. 4 illustrates an example method of determining a first weight set for a first area according to one or more embodiments.

FIG. 5 illustrates an example configuration of an electronic device according to one or more embodiments.

FIG. 6 illustrates an example method of determining an RUL of a battery according to one or more embodiments.

FIG. 7 illustrates an example method of generating a first RUL estimation result according to one or more embodiments.

Throughout the drawings and the detailed description, unless otherwise described or provided, the same or like drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Throughout the specification, when a component, element, or layer is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C” (e.g., each phrase may include any one of the respective items alone, all of the items listed together, and all possible combinations thereof), and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

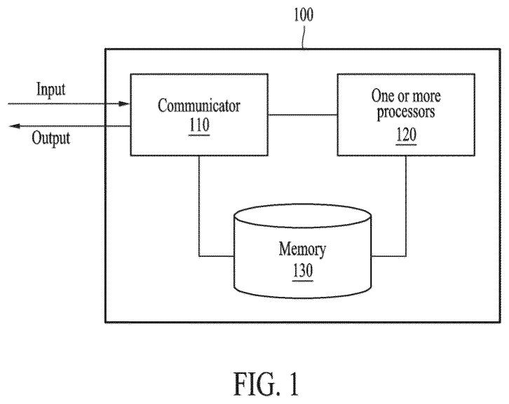

FIG. 1 illustrates an example configuration of an electronic device according to one or more embodiments.

An electronic device 100 may include a communicator 110, one or more processors 120, and a memory 130.

According to one or more embodiments, the electronic device 100 may be implemented as part of a server. The electronic device 100 of the server may generate a look-up table (LUT) used to determine a remaining useful life (RUL) of a battery. The battery may include a capacitor, a secondary cell, and/or a lithium-ion battery that stores electrical power via charging.

The communicator 110 may be connected to the one or more processors 120 and the memory 130 to transmit and receive data to and from the one or more processors 120 and the memory 130. The communicator 110 may also communicate with external devices to transmit and receive data. The expression used herein “transmitting and/or receiving A” may be construed as transmitting and/or receiving information or data indicating A.

The communicator 110 may be implemented as circuitry in the electronic device 100. For example, the communicator 110 may include internal and external buses, and/or serve as an interface linking the device to external components. The communicator 110 may receive data from an external device and transmit the data to the one or more processors 120 and the memory 130.

The one or more processors 120 may process the data received by the communicator 110 and data stored in the memory 130. A “processor” may be a hardware-implemented data processing device having a physically structured circuit to execute desired operations. The desired operations may include, for example, code or instructions included in a program. The hardware-implemented data processing device may include, for example, a microprocessor, a central processing unit (CPU), a processor core, a multi-core processor, a multiprocessor, an application-specific integrated circuit (ASIC), and a field-programmable gate array (FPGA).

The one or more processors 120 may execute computer-readable code (e.g., software) stored in a memory (e.g., the memory 130) and instructions triggered by the one or more processors 120.

The memory 130 may store the data received by the communicator 110 and the data processed by the one or more processors 120. For example, the memory 130 may store software, applications, and/or programs. One such program may include a set of syntaxes coded and executable by the one or more processors 120 to generate an LUT used to determine the RUL of the battery.

The memory 130 may include one or more types of volatile or non-volatile memory, such as random-access memory (RAM), flash memory, a hard disk drive, and an optical disc drive.

The memory 130 may store an instruction set (e.g., software) for operating the electronic device 100. The instruction set for operating the electronic device 100 is executed by the one or more processors 120.

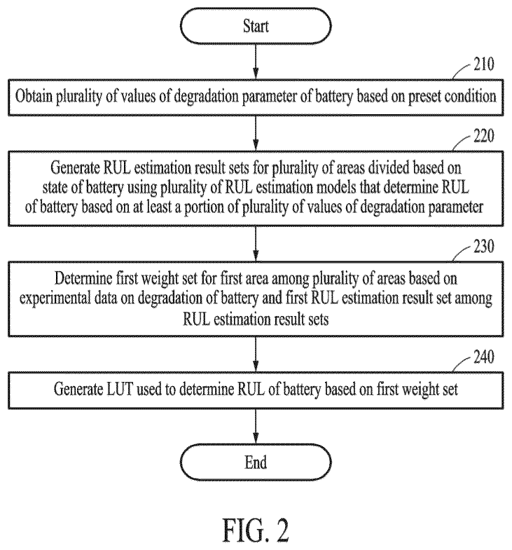

The communicator 110, the processor 120, and the memory 130 are described in detail below with reference to FIGS. 2 through 4.

FIG. 2 illustrates an example method of generating an LUT used to determine an RUL of a battery according to one or more embodiments.

Operations 210 through 240 of FIG. 2 may be performed by an electronic device (e.g., the electronic device 100 of FIG. 1), including one or more processors (e.g., the one or more processors 120 of FIG. 1) and a memory (e.g., the memory 130 of FIG. 1).

In operation 210, the electronic device may obtain a plurality of values of a degradation parameter of a battery based on a preset condition. In one or more embodiments, the degradation parameter of the battery may be a physical property value indicating a tendency to increase or decrease as the battery degrades. For example, the value may be derived from experimental data collected from batteries aged from a fresh state to an end of life (EOL) state, and the degradation parameter may be selected to be input to an RUL model based on the experimental data. For example, the degradation parameter may be a sensing parameter (e.g., voltage, current, or temperature of the battery). For example, the degradation parameter may be a secondary parameter processed/derived from the sensing parameter. For example, the degradation parameter may be a parameter obtained using an electrochemical model. Examples of the degradation parameter may include, but are not limited to, a solid electrolyte interphase (SEI) resistance of a negative electrode, a capacity of a positive electrode active material, an electrode balance shift, and/or a state of health (SOH).

In one or more embodiments, the preset condition may be whether a number of accumulated charging/discharging cycles of the battery reaches a threshold (e.g., a preset number). For example, when the number of accumulated charging/discharging cycles of the battery reaches a preset number such as 1, 51, 101, 151, or 201, a value of the degradation parameter corresponding to that timepoint may be determined and recorded. For example, when the degradation parameter is the SOH, a first SOH may be obtained at a timepoint when the number of accumulated charging/discharging cycles of the battery is 1, a second SOH may be obtained at a timepoint when the number of accumulated charging/discharging cycles of the battery is 51, and a third SOH may be obtained at a timepoint when the number of accumulated charging/discharging cycles of the battery is 101.

Hereinafter, a method of generating an LUT used to determine the RUL of a battery using a single degradation parameter is described, but the description may also be applied to a method using multiple degradation parameters.

In operation 220, the electronic device may generate RUL estimation result sets for a plurality of areas divided based on a state of the battery using a plurality of RUL estimation models that determine the RUL of the battery based on one or more values of the degradation parameter.

In one or more embodiments, the plurality of RUL estimation models may be models based on a set of base RUL estimation models (e.g., 10 types). These base RUL estimation models may include linear regression (ridge), linear regression (LASSO), linear regression (elastic net), decision trees, support vector machine (kernel: linear), support vector machine (kernel: 2nd-order polynomial), support vector machine (kernel: 3rd-order polynomial), support vector machine (kernel: 4th-order polynomial), support vector machine (kernel: sigmoid), support vector machine (kernel: sigmoid), and support vector machine (kernel: RBF). Even when using the same base RUL estimation model, different RUL estimation models may be generated depending on the number of values of the degradation parameter input to the base RUL estimation model. For example, even when using a base RUL estimation model of linear regression (ridge), a first RUL estimation model to which two values of the degradation parameter are applied and a second RUL estimation model to which three values of the degradation parameter are applied may be different models.

According to one or more embodiments, when a minimum number of values used in at least one of the plurality of RUL estimation models among the plurality of values of the degradation parameter is a, a maximum number of values used in at least one of the plurality of RUL estimation models is b, and the number of base RUL estimation models is c, the number of the plurality of RUL estimation models may be up to (b−a+1)×c. For example, when the minimum number of values of the degradation parameter is 2, the maximum number of values of the degradation parameter is 7, and the number of base RUL estimation models is 10, the number of the plurality of RUL estimation models may be up to 60. Since a maximum number of six types of values of the degradation parameter may be input to a single base RUL estimation model, a maximum of six RUL estimation models may be generated for a single base RUL estimation model.

In one or more embodiments, a plurality of areas may be divided based on a state of the battery. For example, the plurality of areas may be divided into a first area where the number of accumulated charging/discharging cycles of the battery is 500 or less, a second area where the number of accumulated charging/discharging cycles of the battery is between 501 and 1000, and a third area where the number of accumulated charging/discharging cycles of the battery is greater than 1000. For example, the plurality of areas may be divided into a first area where the SOH of the battery is 0.9 or greater, a second area where the SOH is 0.8 to less than 0.9, and a third area where the SOH is less than 0.8. The method by which the areas are divided is not limited to the above-described examples.

According to one or more embodiments, when a state of the battery corresponds to the first area and the degradation parameter is the SOH, a first RUL estimation result set may be generated by inputting all or at least a portion of values of the SOH obtained in the first area to each of the plurality of RUL estimation models. For example, when the number of the values of the SOH obtained in the first area is at most 4, an RUL estimation model that requires 5 or more values of the SOH as input may not be able to generate an RUL estimation result. For example, when the number of the values of the SOH obtained in the first area is at most 4, an RUL estimation model that requires 3 (or 1 or 2) values of the SOH as input may generate an RUL estimation result using the most recently obtained values.

According to one or more embodiments, when a state of the battery corresponds to the first area and the degradation parameter is the SOH, the first RUL estimation result set may be generated by inputting two values of the SOH, which is the minimum number of values, to the base RUL estimation models. And, by inputting three values of the SOH to the base RUL estimation models, the first RUL estimation result set may be generated. And, by inputting six values of the SOH, which is the maximum number of values, to the base RUL estimation models, the first RUL estimation result set may be generated.

A method of generating the first RUL estimation result set corresponding to the first area among the plurality of areas is described in detail below with reference to FIG. 3.

In operation 230, the electronic device may determine a first weight set for the first area among the plurality of areas based on experimental data on degradation of the battery and the first RUL estimation result set among the RUL estimation result sets. The experimental data on the degradation of the battery may represent RUL statistics (or RUL ground truth) corresponding to RUL estimation as a measure of the degradation tendency of the battery.

In one or more embodiments, the electronic device may determine the accuracy of each of the estimation results within the first RUL estimation result set based on the experimental data. For example, an estimation accuracy may be determined for each of the RUL estimation results for the first area estimated using at least a portion of the 60 RUL estimation models described above.

According to one or more embodiments, the electronic device may determine a preset number of first RUL estimation models from among the RUL estimation models. For example, all RUL estimation models that generate the first RUL estimation result may be determined to be the first RUL estimation models. For example, a subset/portion of the RUL estimation models may be determined/selected to be the first RUL estimation models based on the estimation accuracy. The electronic device may determine the first weight set for the first RUL estimation result set (or the first RUL estimation models) such that a weighted sum of the estimation results within the first RUL estimation result set of the first RUL estimation models corresponds to statistics of various experimental results for the same battery type.

In one or more embodiments, when the plurality of areas includes the first area, the second area, and the third area, the first weight set may be generated for the first area, a second weight set may be generated for the second area, and a third weight set may be generated for the third area.

An RUL estimation model with high performance in estimating the RUL in the first area but poor performance in estimating the RUL in the second area may have high weights in the first weight set but may not be used for RUL estimation in the second area or may have low weights in the second weight set.

For example, the first weight set for all 60 RUL estimation models may be generated for the first area. As another example, the first weight set for a preset number of RUL estimation models among the 60 RUL estimation models may be generated for the first area.

According to one or more embodiments, the first weight set for ten base RUL estimation models may be generated for the first area, corresponding to the number of values of the degradation parameter being used. For example, the first weight set may be generated for the number of values of 2 (e.g., a minimum number) of the degradation parameter, the first weight set may be generated for the number of values of 3-5 (e.g., intermediate) of the degradation parameter, and the first weight set may be generated for the number of values of 6 (e.g., a maximum number) of the degradation parameter.

In operation 240, the electronic device may generate an LUT used to determine the RUL of the battery using the first weight set. For example, when the plurality of areas includes the first area, the second area, and the third area, the LUT may include the first weight set for the first area, the second weight set for the second area, and the third weight set for the third area.

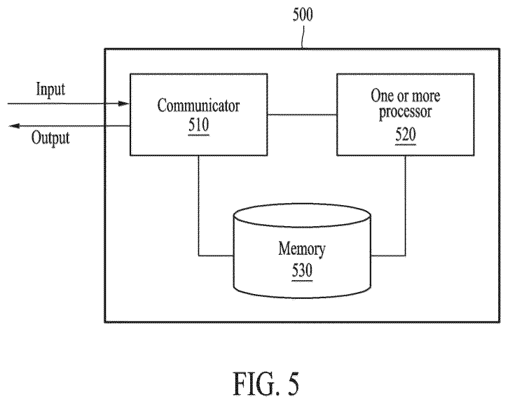

According to one or more embodiments, the generated LUT may be used by other electronic devices (e.g., mobile terminals, vehicles) equipped with the battery to estimate the RUL of the battery. A method of estimating the RUL of the battery using the LUT is described in detail below with reference to FIGS. 5 through 7.

FIG. 3 illustrates an example method of generating an RUL estimation result set for a plurality of areas according to one or more embodiments.

Operations 310 and 320 of FIG. 3 may correspond to operation 220 described above with reference to FIG. 2. That is, operation 220 may include the processes of operations 310 and 320.

Operations 310 and 320 may be performed by an electronic device (e.g., the electronic device 100 of FIG. 1). For example, the electronic device may include one or more processors (e.g., the one or more processors 120 of FIG. 1) and a memory (e.g., the memory 130 of FIG. 1).

In operation 310, the electronic device may generate a first RUL estimation result set corresponding to the first area using first RUL estimation models among a plurality of RUL estimation models that determine an RUL of the battery based on first values among a plurality of values of a degradation parameter corresponding to a first area among a plurality of areas. The first values of the degradation parameter may be values used in an RUL estimation model.

For example, when the first area is an area in which the number of accumulated charging/discharging cycles of a battery is 500 or less, the plurality of values of the degradation parameter corresponding to the first area may be values (e.g., SOH values of the battery) obtained according to satisfying a preset condition (e.g., the number of accumulated charging/discharging cycles of the battery increases by 50) when the number of accumulated charging/discharging cycles of the battery is 500 or less.

For example, when the values of the degradation parameter are obtained at timepoints when the number of accumulated charging/discharging cycles of the battery is 1, 51, 101, 151, and 201, and an RUL estimation timepoint is when the number of accumulated charging/discharging cycles of the battery is 201, the electronic device may use a total of these five values (i.e., values 1, 51, 101, 151, and 201) of the degradation parameter. RUL estimation models that require six or more values of the degradation parameter may not generate RUL estimation results. RUL estimation models that require three or more values of the degradation parameter may use the three most recent values of the five obtained values of the degradation parameter (i.e., values from 101, 151, and 201) to generate RUL estimation results.

According to one or more embodiments, the electronic device may generate the first RUL estimation result set at each of a plurality of timepoints within the first area. The electronic device may determine a first weight set for the first area, based on the generated first RUL estimation result sets and experimental data on the degradation of the battery.

In operation 320, the electronic device may generate a second RUL estimation result set corresponding to the second area using second RUL estimation models among the plurality of RUL estimation models that generate the RUL of the battery based on second values among a plurality of values of a degradation parameter corresponding to the second area among the plurality of areas. For example, the plurality of values of the degradation parameter corresponding to the second area may include values of the degradation parameter obtained in the first area and values of the degradation parameter obtained in the second area. As another example, the plurality of values of the degradation parameter corresponding to the second area may include only the values of the degradation parameter obtained in the second area, excluding the values of the degradation parameter obtained in the first area. The second values of the degradation parameter may be values used in the second RUL estimation models.

According to one or more embodiments, the electronic device may generate a second RUL estimation result set at each of a plurality of timepoints within the second area. The electronic device may determine a second weight set for the second area based on the generated second RUL estimation result sets and experimental data on the degradation of the battery.

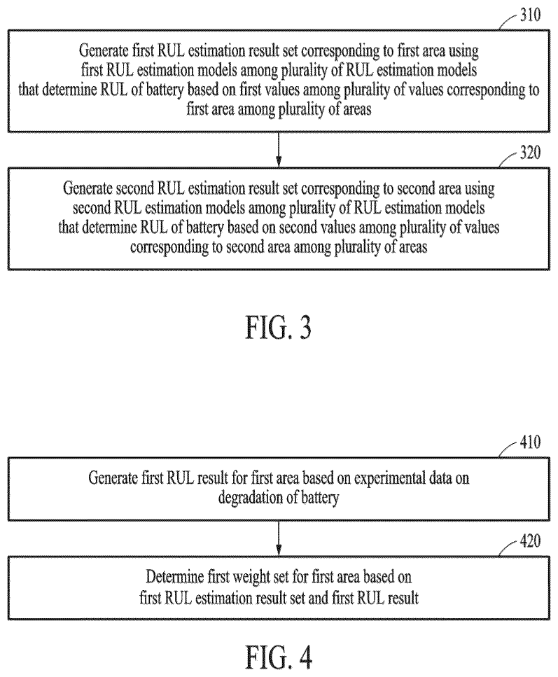

FIG. 4 illustrates an example method of determining a first weight set for a first area according to one or more embodiments.

Operations 410 and 420 of FIG. 4 may correspond to operation 230 described above with reference to FIG. 2. For example, operation 230 may include the processes of operations 410 and 420.

Operations 410 and 420 may be performed by an electronic device (e.g., the electronic device 100 of FIG. 1). For example, the electronic device may include one or more processors (e.g., the one or more processors 120 of FIG. 1) and a memory (e.g., the memory 130 of FIG. 1).

In operation 410, the electronic device may generate a first RUL result for a first area based on experimental data reflecting degradation of a battery. The first RUL result for the first area may represent an RUL statistic or RUL ground truth that corresponds to an RUL estimate for the first area.

In operation 420, the electronic device may determine a first weight set for the first area based on a first RUL estimation result set and the first RUL result.

In one or more embodiments, the electronic device may determine an accuracy of each of the estimation results within the first RUL estimation result set based on the first RUL result. For example, an estimation accuracy may be determined for each of the RUL estimation results for the first area estimated by at least a portion/subset of the 60 RUL estimation models described above with reference to FIG. 2. For example, an estimation accuracy may be determined for each of the RUL estimation results for the first area estimated by the 10 base RUL estimation models described above with reference to FIG. 2.

According to one or more embodiments, the electronic device may determine/select a preset number of first RUL estimation models from among the RUL estimation models. For example, all RUL estimation models that generate a first RUL estimation result may be determined to be the first RUL estimation models. For example, a portion/subset of the RUL estimation models may be determined to be the first RUL estimation models based on the estimation accuracy. The electronic device may determine a first weight set for the first RUL estimation result set (or the first RUL estimation models) such that a weighted sum of estimation results within the first RUL estimation result set of the first RUL estimation models aligns with or approximates the first RUL result. When the number of first RUL estimation models is S, the first weight set may include S corresponding weights.

According to one or more embodiments, the electronic device may determine first candidate estimation results among the estimation results of the first RUL estimation result set, based on the first RUL result. For example, a preset number of the first candidate estimation results may be determined based on the accuracy (or similarity) between each of the estimation results of the first RUL estimation result set and the first RUL result. For example, the first candidate estimation results may be determined in which the accuracy between each of the estimation results of the first RUL estimation result set and the first RUL result exceeds a preset threshold value. The electronic device may determine the first weight set for the first area based on the first candidate estimation results and the first RUL result. The electronic device may determine the first weight set for the first RUL estimation result set (or the first RUL estimation models) such that a weighted sum of the first candidate estimation results aligns with or approximates the first RUL result.

FIG. 5 illustrates an example configuration of an electronic device according to one or more embodiments.

An electronic device 500 may include a communicator 510, one or more processors 520, and a memory 530. The electronic device may be powered by a battery, which may include a capacitor, a secondary battery, and/or a lithium-ion battery for storing power through charging. The electronic device 500 may include a display and other components that receive power from the battery.

According to one or more embodiments, the electronic device 500 may be a mobile terminal.

According to one or more embodiments, the electronic device 500 may be included in a vehicle.

The communicator 510 may interface with the one or more processors 520 and the memory 530 to transmit and receive data internally. The communicator 510 may also be connected to an external device to facilitate data exchange between the electronic device and the external device.

The communicator 510 may be implemented as circuitry in the electronic device 500. For example, the communicator 510 may include internal and external buses. In another example, the communicator 510 may serve as an interface element that connects the electronic device 500 to an external device. The communicator 510 may receive data from the external device and transmit the data to the one or more processors 520 and/or the memory 530.

The one or more processors 520 may process the data received from the communicator 510 and data stored in the memory 530. The one or more processors 520 may execute computer-readable code (e.g., software) stored in a memory (e.g., the memory 530) and instructions triggered by the one or more processors 520.

The memory 530 may store the data received from the communicator 510 and the data processed by the one or more processors 520. For example, the memory 530 may store a program (or an application, or software). For example, the program being stored may be a set of syntaxes that are coded and executable by the one or more processors 520 to determine an RUL of a battery. The memory 530 may store an LUT used to determine the RUL of the battery. The LUT may be generated by an electronic device (e.g., the electronic device 100 described above with reference to FIGS. 1 through 4). The memory 530 may store a plurality of RUL estimation models (e.g., base RUL estimation models) used to determine the RUL of the battery.

The memory 530 may include one or more types of volatile and non-volatile memories, such as RAM, flash memories, hard disk drives, and optical disc drives.

The memory 530 may also store an instruction set (e.g., software) for operating the electronic device 500. The instruction set for operating the electronic device 500 is executed by the one or more processors 520.

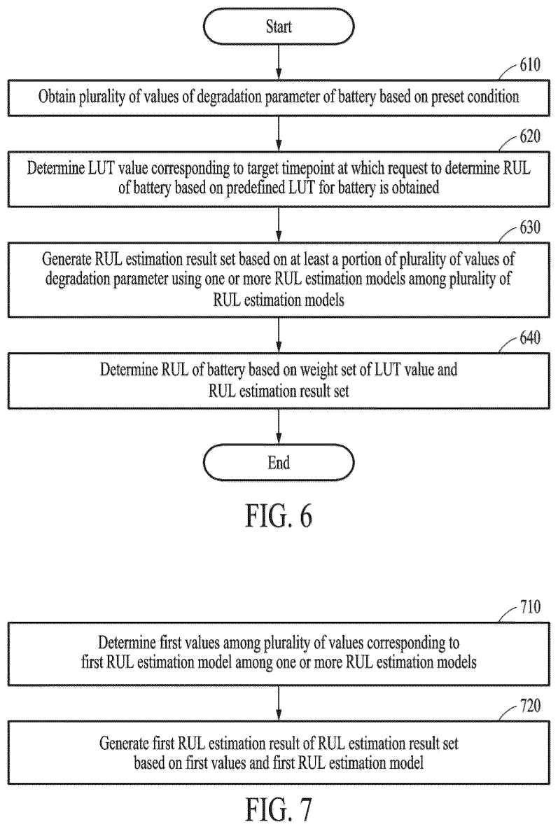

The communicator 510, the one or more processors 520, and the memory 530 are described further below with reference to FIGS. 6 and 7.

FIG. 6 illustrates an example method of determining an RUL of a battery according to one or more embodiments.

Operations 610 through 640 of FIG. 6 may be performed by an electronic device (e.g., the electronic device 500 of FIG. 5). For example, the electronic device may include one or more processors (e.g., the one or more processors 520 of FIG. 5) and a memory (e.g., the memory 530 of FIG. 5).

In operation 610, the electronic device may obtain multiple values of a degradation parameter of a battery based on a preset condition. In one or more embodiments, the degradation parameter of the battery may be a physical property value indicating a tendency to increase or decrease as the battery degrades. For example, the degradation parameter may be an SOH, but is not limited thereto.

In one or more embodiments, the preset condition may be whether the number of accumulated charging/discharging cycles of the battery reaches a preset number. For example, when the number of accumulated charging/discharging cycles of the battery reaches a preset number such as 1, 51, 101, 151, or 201, a value of the degradation parameter corresponding to that timepoint may be determined. For example, when the degradation parameter is the SOH, a first SOH may be obtained at a timepoint when the number of accumulated charging/discharging cycles of the battery is 1, a second SOH may be obtained at a timepoint when the number of accumulated charging/discharging cycles of the battery is 51, and a third SOH may be obtained at a timepoint when the number of accumulated charging/discharging cycles of the battery is 101.

While the following description refers to a method of determining an RUL of a battery using a single degradation parameter, the description may also be applicable to methods using multiple degradation parameters.

In operation 620, the electronic device may determine an LUT value corresponding to a target timepoint at which a request to determine an RUL of the battery based on a predefined LUT for the battery is obtained. For example, the LUT value may include a weight set comprising weights assigned to multiple RUL estimation models or base RUL estimation models.

According to one or more embodiments, a request to determine the RUL of the battery may be generated when a state of the battery matches a preset state/condition, and the electronic device may be configured to obtain such a request. For example, when the number of accumulated charging/discharging cycles of the battery reaches a preset number, a request to determine the RUL of the battery may be generated.

According to one or more embodiments, a request to determine the RUL of the battery may be generated periodically. For example, the request may be generated once a week.

In addition, when an operating system of the electronic device is updated, a request to determine the RUL of the battery may be generated.

A request to determine the RUL of the battery may also be generated in response to user input, and the electronic device may be configured to receive such a request.

According to one or more embodiments, a target area may be determined based on a target timepoint at which the request is obtained among a plurality of areas divided based on the state of the battery. For example, the plurality of areas may be divided into a first area where the number of accumulated charging/discharging cycles of the battery is 500 or less, a second area where the number of accumulated charging/discharging cycles of the battery is between 501 and 1000, and a third area where the number of accumulated charging/discharging cycles of the battery exceeds 1000. For example, when the number of accumulated charging/discharging cycles of the battery at the target timepoint is 210, an area corresponding to the target timepoint may be determined to be the first area. The electronic device may determine a first weight set for the first area.

According to one or more embodiments, the electronic device may determine a first RUL estimation result set for the first area based on the number of values of the degradation parameter that are currently obtained. For example, when the number of values of the degradation parameter that are currently obtained is 3, a first weight set may be determined for the number of values of 3 of the degradation parameter from among a first weight set for the number of values of 2 (e.g., a minimum number) of the degradation parameter, a first weight set for the number of values of 3 to 5 (e.g., intermediate) of the degradation parameter, and a first weight set for the number of values of 6 (e.g., a maximum number) of the degradation parameter.

In operation 630, the electronic device may generate an RUL estimation result set using at least a portion of a plurality of values of the degradation parameter and one or more RUL estimation models among a plurality of RUL estimation models.

In one or more embodiments, the electronic device may generate the RUL estimation result set using, for example, 60 RUL estimation models. For example, when the number of values of the degradation parameter that are obtained based on the target timepoint is 4, an RUL estimation model that requires 5 or more values may not be able to estimate the RUL. In the above-described example, less than 60 RUL estimation results may be generated.

In one or more embodiments, the electronic device may generate the RUL estimation result set using, for example, 10 base RUL estimation models. For each of the base RUL estimation models, the number of values of the degradation parameter obtained based on the target timepoint may be used. For example, when four values of the degradation parameter are obtained based on the target timepoint, the four values of the degradation parameter may be input to each of the base RUL estimation models. In the above-described example, 10 RUL estimation results may be generated.

According to one or more embodiments, the electronic device may determine/select one or more RUL estimation models among a plurality of RUL estimation models based on a weight set. For example, an RUL estimation model may be determined that has non-zero weights among weights in the weight set. Since an RUL estimation result of an RUL estimation model having zero weight does not contribute to an RUL determination, the RUL estimation model having zero weight may not generate an RUL estimation result.

In operation 640, the electronic device may determine the RUL of the battery based on the weight set of the LUT value and the RUL estimation result set. For example, the electronic device may determine a final RUL of the battery by weighting the RUL estimation results of the RUL estimation result set based on the weight set.

FIG. 7 illustrates an example method of generating a first RUL estimation result according to one or more embodiments.

Operations 710 and 720 of FIG. 7 may correspond to operation 630 described above with reference to FIG. 6. For example, operation 630 may include the processes of operations 710 and 720.

Operations 710 and 720 may be performed by an electronic device (e.g., the electronic device 100 of FIG. 1). For example, the electronic device may include one or more processors (e.g., the one or more processors 120 of FIG. 1) and a memory (e.g., the memory 130 of FIG. 1).

In operation 710, the electronic device may determine/select first values among a plurality of values corresponding to a first RUL estimation model among one or more RUL estimation models. For example, when eight values of a degradation parameter are obtained based on a target timepoint and six values of the degradation parameter are input to a first RUL estimation model, the most recent six values of the degradation parameter among the eight values of the degradation parameter may be determined to be first values.

In operation 720, the electronic device may generate a first RUL estimation result of an RUL estimation result set based on the first values among the values of the degradation parameter and the first RUL estimation model. For example, the first RUL estimation result may be generated by inputting the first values to the first RUL estimation model.

The electronic devices, computing devices, processors, memory, batteries, electronic device 100/500, communicator 110/510, processors 120/520, memory 130/530, and other apparatus, devices, and components described herein with respect to FIGS. 1-7 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software include higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A processor-implemented method, the method comprising:
generating remaining useful life (RUL) estimation result sets for a plurality of areas divided based on a state of a battery, using a plurality of RUL estimation models that determine an RUL of the battery, based on at least a portion of a plurality of values of a degradation parameter of the battery;
determining a first weight set for a first area among the plurality of areas, based on experimental data on degradation of the battery and a first RUL estimation result set among the RUL estimation result sets; and
generating a look-up table (LUT) to determine the RUL of the battery based on the first weight set.

2. The method of claim 1, wherein the plurality of values of the degradation parameter is obtained based on a preset condition, and the preset condition comprises whether a number of accumulated charging/discharging cycles reaches a preset number.

3. The method of claim 1, wherein the degradation parameter of the battery comprises a state of health (SOH) of the battery.

4. The method of claim 1, wherein:
a minimum number of values used in one or more of the plurality of RUL estimation models among the plurality of values of the degradation parameter is a;
a maximum number of values used in one or more of the plurality of RUL estimation models among the plurality of values of the degradation parameter is b;
a number of base RUL estimation models is c; and
a number of the plurality of RUL estimation models is less than or equal to (b−a+1)×c.

5. The method of claim 1, wherein the generating of the RUL estimation result sets comprises:
generating the first RUL estimation result set corresponding to the first area, using first RUL estimation models among the plurality of RUL estimation models, based on first values among the plurality of values corresponding to the first area; and
generating a second RUL estimation result set corresponding to a second area among the plurality of areas, using second RUL estimation models among the plurality of RUL estimation models, based on second values among the plurality of values corresponding to the second area.

6. The method of claim 1, wherein the determining of the first weight set comprises:
generating a first RUL result for the first area based on the experimental data; and
determining the first weight set for the first area based on the first RUL estimation result set and the first RUL result.

7. The method of claim 6, wherein the determining of the first weight set further comprises:
determining, based on the first RUL result, first candidate estimation results among estimation results of the first RUL estimation result set; and
determining the first weight set for the first area based on the first candidate estimation results and the first RUL result.

8. A non-transitory computer-readable storage medium storing one or more programs including instructions that, when executed by one or more processors of an electronic device individually or collectively, cause the electronic device to perform the method of claim 1.

9. An electronic device comprising:
one or more processors including processing circuitry; and
memory including one or more storage media storing instructions that, when executed by the one or more processors individually or collectively, cause the electronic device to:
generate remaining useful life (RUL) estimation result sets for a plurality of areas divided based on a state of a battery, using a plurality of RUL estimation models that determine an RUL of the battery, based on at least a portion of a plurality of values of a degradation parameter of the battery;
determine a first weight set for a first area among the plurality of areas, based on experimental data on degradation of the battery and a first RUL estimation result set among the RUL estimation result sets; and
generate a look-up table (LUT) to determine the RUL of the battery based on the first weight set.

10. The electronic device of claim 9, wherein the plurality of values of the degradation parameter is obtained based on a preset condition, and the preset condition comprises whether a number of accumulated charging/discharging cycles reaches a preset number.

11. The electronic device of claim 9, wherein the degradation parameter of the battery comprises a state of health (SOH) of the battery.

12. The electronic device of claim 9, wherein:
a minimum number of values used in one or more of the plurality of RUL estimation models among the plurality of values of the degradation parameter is a;
a maximum number of values used in one or more of the plurality of RUL estimation models among the plurality of values of the degradation parameter is b;
a number of base RUL estimation models is c; and
a number of the plurality of RUL estimation models is less than or equal to (b−a+1)×c.

13. The electronic device of claim 9, wherein the instructions, when executed by the one or more processors individually or collectively, cause the electronic device to:
generate the first RUL estimation result set corresponding to the first area, using first RUL estimation models among the plurality of RUL estimation models, based on first values among the plurality of values corresponding to the first area; and
generate a second RUL estimation result set corresponding to a second area among the plurality of areas, using second RUL estimation models among the plurality of RUL estimation models, based on second values among the plurality of values corresponding to the second area.

14. The electronic device of claim 13, wherein the instructions, when executed by the one or more processors individually or collectively, cause the electronic device to:
generate a first RUL result for the first area based on the experimental data; and
determine the first weight set for the first area based on the first RUL estimation result set and the first RUL result.

15. The electronic device of claim 14, wherein the instructions, when executed by the one or more processors individually or collectively, cause the electronic device to:
determine, based on the first RUL result, first candidate estimation results among estimation results of the first RUL estimation result set; and
determine the first weight set for the first area based on the first candidate estimation results and the first RUL result.

16. A mobile terminal comprising:
a display;
a battery supplying power to the display;
one or more processors each including processing circuitry; and
memory including one or more storage media storing instructions that, when executed by the one or more processors individually or collectively, cause the mobile terminal to:
determine a look-up table (LUT) value corresponding to a target timepoint at which a request to determine a remaining useful life (RUL) of the battery based on a predefined LUT for the battery is obtained, wherein the LUT value comprises a weight set for a plurality of RUL estimation models;
generate an RUL estimation result set based on at least a portion of a plurality of values of a degradation parameter of the battery using one or more of the plurality of RUL estimation models; and
determine the RUL of the battery based on the weight set of the LUT value and the RUL estimation result set.

17. The mobile terminal of claim 16, wherein the plurality of values of the degradation parameter is obtained based on a preset condition, and the preset condition comprises whether a number of accumulated charging/discharging cycles reaches a preset number.

18. The mobile terminal of claim 16, wherein the degradation parameter comprises a state of health (SOH) of the battery.

19. The mobile terminal of claim 16, wherein the instructions, when executed by the one or more processors individually or collectively, cause the mobile terminal to:
determine the one or more RUL estimation models based on the weight set.

20. The mobile terminal of claim 16, wherein the instructions, when executed by the one or more processors individually or collectively, cause the mobile terminal to:
determine first values among the plurality of values corresponding to a first RUL estimation model among the one or more RUL estimation models; and
generate a first RUL estimation result of the RUL estimation result set based on the first values and the first RUL estimation model.
